(19) United States
(12) Patent Application Publication
(10) Pub. No.: US 2026/0282548 A1
(43) Pub. Date: Sep. 17, 2026

(54) DISPLAY DEVICE AND ELECTRONIC DEVICE

(71) Applicant: Samsung Display Co., Ltd., Yongin-si (KR)

(72) Inventors: Kyung Bae KIM, Yongin-si (KR); Jang Mi KANG, Yongin-si (KR); Gyung Soon PARK, Yongin-si (KR)

(21) Appl. No.: 19/553,667

(22) Filed: Mar. 2, 2026

(30) Foreign Application Priority Data
Mar. 11, 2025 (KR) 10-2025-0031043

(51) Int. Cl. H10D 86/60; H10D 86/40; H10K 59/12; H10K 59/122

(52) U.S. Cl. CPC H10D 86/60; H10D 86/423; H10K 59/1201; H10K 59/122

(57) ABSTRACT

Disclosed herein are a display device and an electronic device in which short-channel effects can be reduced or prevented while ensuring a high driving speed of a driving circuit, the display device including a substrate having a display area and a non-display area, a first transistor and a second transistor at the display area, at least one of which including an oxide semiconductor transistor, a first electrode above the second transistor, a pixel-defining layer above the first electrode, a light-emitting layer above the pixel-defining layer to be connected to the first electrode, a second electrode above the light-emitting layer, and a third transistor including a field effect transistor at the non-display area.

### CROSS-REFERENCE TO RELATED APPLICATION

The present application claims priority to, and the benefit of, Korean Patent Application No. 10-2025-0031043, filed on March 11, 2025, in the Korean Intellectual Property Office, the entire disclosure of which is incorporated herein by reference.

### BACKGROUND

### 1. Field

The present disclosure relates to a display device and an electronic device in which short-channel effects can be reduced or prevented while ensuring a high driving speed of a driving circuit.

### 2. Description of the Related Art

An organic light-emitting display apparatus includes display elements having luminance varying depending on electric current, for example, organic light-emitting diodes.

### SUMMARY

Aspects of the present disclosure provide a display device and an electronic device in which short-channel effects can be reduced or prevented while ensuring a high driving speed of a driving circuit.

According to an aspect of the present disclosure, there is provided a display device including a substrate having a display area and a non-display area, a first transistor and a second transistor at the display area, at least one of which including an oxide semiconductor transistor, a first electrode above the second transistor, a pixel-defining layer above the first electrode, a light-emitting layer above the pixel-defining layer to be connected to the first electrode, a second electrode above the light-emitting layer, and a third transistor including a field effect transistor at the non-display area.

The oxide semiconductor transistor may include an N-type transistor.

The field effect transistor may include a P-type transistor.

The oxide semiconductor transistor may include an indium-gallium-zinc-oxide or indium-gallium-zinc-tin oxide.

The field effect transistor may include a MOSFET.

The display device may further include a capacitor in the display area.

The capacitor may be between the substrate and the first transistor.

The capacitor may include capacitor electrodes.

The capacitor may include a metal-oxide-metal capacitor.

The capacitor may be connected to the first transistor.

The display device may further include a power connection electrode in the display area.

The power connection electrode may be connected to the first transistor.

The display device may further include a connection electrode in the non-display area.

The connection electrode may be provided as multiple connection electrodes.

The connection electrode may be connected to the third transistor.

According to another aspect of the present disclosure, there is provided an electronic device including a display device including a substrate having a display area and a non-display area, a first transistor and a second transistor at the display area, at least one of which including an oxide semiconductor transistor, a first electrode above the second transistor, a pixel-defining layer above the first electrode, a light-emitting layer above the pixel-defining layer and connected to the first electrode, a second electrode above the light-emitting layer, and a third transistor including a field effect transistor at the non-display area.

The oxide semiconductor transistor may include an N-type transistor.

The field effect transistor may include a P-type transistor.

The oxide semiconductor transistor may include an indium-gallium-zinc-oxide or indium-gallium-zinc-tin oxide.

The electronic device may include a smartphone, a tablet PC, a laptop computer, a TV, a desktop monitor, smart glasses, a smart watch, a head-mounted display, or a display for vehicles.

According to one or more embodiments of the present disclosure, short-channel effects can be reduced or prevented while ensuring a high driving speed of a driving circuit.

For example, a driving circuit of the non-display area may include a MOSFET, while the driving circuit include oxide-based transistors. Accordingly, short-channel effects can be reduced or prevented in the display area while ensuring a high driving speed of the driving circuits in the non-display area.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is an exploded, perspective view showing a display device according to one or more embodiments of the present disclosure;

FIG. 2 is a block diagram showing a display device according to one or more embodiments of the present disclosure;

FIG. 3 is a view showing an example of a layout of a display panel according to one or more embodiments of the present disclosure;

FIGS. 4 and 5 are layout diagrams showing examples of the display area of FIG. 3;

FIG. 6 is a cross-sectional view of a driving circuit of the display area and a circuit of a pixel of the non-display area of FIG. 3;

FIG. 7 is a cross-sectional view of a circuit of a pixel and a light-emitting element of FIG. 3;

FIGS. 8, 9, 10, and 11 are process cross-sectional views for illustrating a method of manufacturing a display device according to one or more embodiments;

FIG. 12 is of block diagram of an electronic device according to one or more embodiments of the present disclosure; and

FIGS. 13, 14, and 15 are schematic diagrams of electronic devices according to various embodiments.

The aspects of the present disclosure are not limited to the above-described aspects and other aspects which are not described herein will become apparent to those skilled in the art from the following description.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature’s relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XY, YZ, and XZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When "C to D" is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are only used to distinguish one element, member, component, region, area, layer, section, or portion from another element, member, component, region, area, layer, section, or portion. Thus, a first element, component, region, layer, or section described below could be termed a second element, component, region, layer, or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/- 5 % of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ± 30%, 20%, 10%, 5% of the stated value. Further, the use of “may” when describing embodiments of the present disclosure refers to “one or more embodiments of the present disclosure.” Furthermore, the expression “being the same” may mean “being substantially the same.” In other words, the expression “being the same” may include a range that can be tolerated by those of ordinary skill in the art. The other expressions may also be expressions from which “substantially” has been omitted.

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

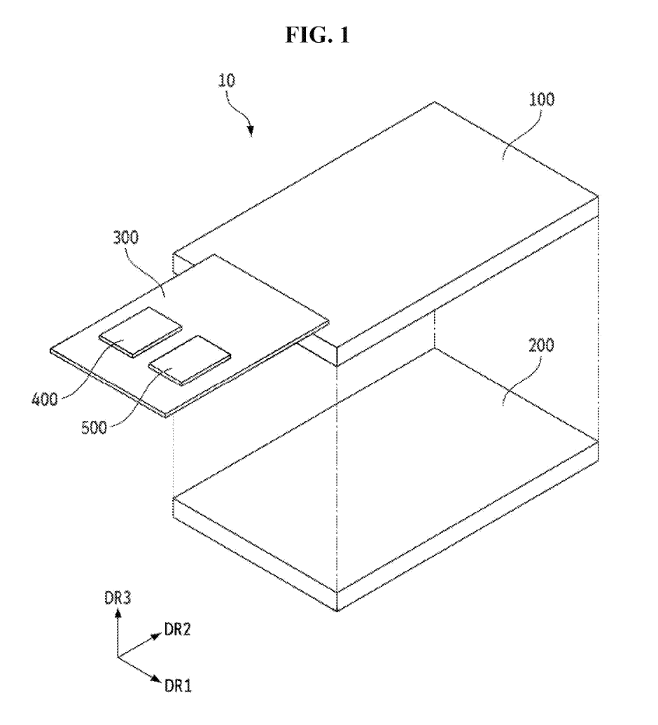

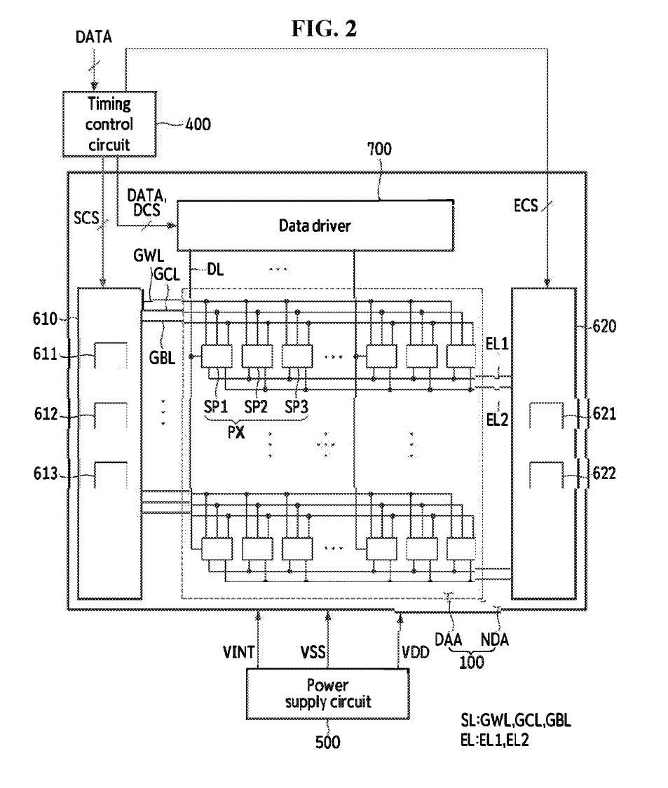

FIG. 1 is an exploded, perspective view showing a display device according to one or more embodiments of the present disclosure. FIG. 2 is a block diagram showing a display device according to one or more embodiments of the present disclosure.

Referring to FIGS. 1 and 2, a display device 10 displays a moving image or a still image. The display device 10 may be employed by portable electronic devices, such as a mobile phone, a smart phone, a tablet PC, a mobile communications terminal, an electronic notebook, an electronic book, a portable multimedia player (PMP), a navigation device and an ultra-mobile PC (UMPC). For example, the display device 10 of the present disclosure may be used as a display unit of a television, a laptop computer, a monitor, an electronic billboard, or the Internet of Things (IOT). Alternatively, the display device 10 of the present disclosure may be applied to a smart watch, a watch phone, or a head-mounted display (HMD) for implementing virtual reality and augmented reality.

According to one or more embodiments, the display device 10 includes a display panel 100, a heat dissipation layer 200, a circuit board 300, a timing control circuit 400, and a power supply circuit 500.

The display panel 100 may have a shape similarly to a rectangular shape when viewed from the top. For example, the display panel 100 may have a shape similar to a rectangle having shorter sides in a first direction DR1, and longer sides in a second direction DR2 crossing the first direction DR1 when viewed from the top. In the display panel 100, the corners where the shorter sides in the first direction DR1 meet the longer sides in the second direction DR2 may be rounded with a curvature (e.g., predetermined curvature) or may be a right angle. The shape of the display panel 100 when viewed from the top is not limited to a rectangular shape, but may be formed in a shape similar to other polygonal shapes, a circular shape, or an elliptical shape. The shape of the display device 10 may follow the shape of the display panel 100 when viewed from the top, but the embodiments of the present disclosure are not limited thereto.

The display panel 100 may include a plurality of pixels PX, a plurality of scan lines SL, a plurality of emission control lines EL, a plurality of data lines DL, a scan driver 610, an emission driver 620, and a data driver 700. The display panel 100 may be divided into a display area DAA where images are displayed, and a non-display area NDA where no image is displayed as shown in FIG. 2.

The plurality of pixels PX may be arranged in the display area DAA. The pixels PX may be arranged in a matrix in the first direction DR1 and the second direction DR2. The scan lines SL and the emission control lines EL may be extended in the first direction DR1 and may be arranged in the second direction DR2. The data lines DL may be extended in the second direction DR2 and may be arranged in the first direction DR1.

The plurality of scan lines SL includes a plurality of write scan lines GWL, a plurality of control scan lines GCL, and a plurality of bias scan lines GBL. The plurality of emission control lines EL includes a plurality of first emission control lines EL1 and a plurality of second emission control lines EL2.

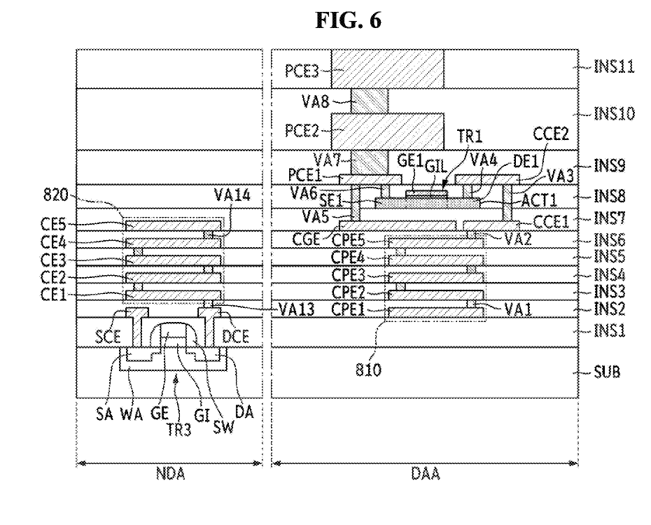

The plurality of pixels PX includes a plurality of sub-pixels SP1, SP2, and SP3. The sub-pixels SP1, SP2, and SP3 may include transistors, and the plurality of transistors may be formed by a semiconductor process and be placed in a semiconductor substrate SUB (see FIG. 6). For example, the plurality of transistors of the data driver 700 may be formed as a complementary metal oxide semiconductor (CMOS), but the present disclosure is not limited thereto.

Each of the sub-pixels SP1, SP2, and SP3 may be connected to one of the write scan lines GWL, one of the control scan lines GCL, one of the bias scan lines GBL, one of the first emission control lines EL1, one of the second emission control lines EL2, and one of the data lines DL. Each of the sub-pixels SP1, SP2, and SP3 may receive the data voltage from the data line DL according to the write scan signal from the write scan line GWL, and may allow the light-emitting elements to emit light according to the data voltage.

The scan driver 610, the emission driver 620, and the data driver 700 may be located in the non-display area NDA.

The scan driver 610 includes a plurality of scan transistors, and the emission driver 620 includes a plurality of light-emitting transistors. A plurality of scan transistors and a plurality of light-emitting transistors are formed via a semiconductor process and may be formed on the semiconductor substrate SUB (see FIG. 6). For example, a plurality of scan transistors and a plurality of light-emitting transistors may be formed of CMOS. It should be understood, however, that the embodiments of the present disclosure are not limited thereto.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan-timing control signal SCS from the timing control circuit 400. The write scan signal output unit 611 may generate write scan signals according to the scan-timing control signal SCS from the timing control circuit 400, and may sequentially output them to the write scan lines GWL. The control scan signal output unit 612 may generate control scan signals according to the scan-timing control signal SCS, and may sequentially output them to the control scan lines GCL. The bias scan signal output unit 613 may generate bias scan signals according to the scan-timing control signal SCS, and may sequentially output them to the bias scan lines EBL.

The emission driver 620 includes a first emission control driver 621 and a second emission control driver 622. Each of the first emission control driver 621 and the second emission control driver 622 may receive an emission-timing control signal ECS from the timing control circuit 400. The first emission control driver 621 may generate first emission control signals according to the emission-timing control signal ECS, and may sequentially output them to the first emission control lines EL1. The second emission control driver 622 may generate second emission control signals according to the emission-timing control signal ECS, and may sequentially output them to the second emission control lines EL2.

The data driver 700 may include a plurality of data transistors, and the plurality of data transistors may be formed via a semiconductor process and may be formed on the semiconductor substrate SUB (see FIG. 6). For example, a plurality of data transistors may be formed of CMOS transistors. It should be understood, however, that the embodiments of the present disclosure are not limited thereto.

The data driver 700 may receive digital video data DATA and a data-timing control signal DCS from the timing control circuit 400. The data driver 700 converts the digital video data DATA into analog data voltages according to the data-timing control signal DCS, and outputs the analog data voltages to the data lines DL. In doing so, the sub-pixels SP1, SP2, and SP3 are selected by the write scan signal of the scan driver 610, and data voltages may be applied to the selected sub-pixels SP1, SP2, and SP3.

The heat dissipation layer 200 may overlap with the display panel 100 in a third direction DR3, which is the thickness direction of the display panel 100. The heat dissipation layer 200 may be located on one surface of the display panel 100 (e.g., on the rear surface). The heat dissipation layer 200 serves to release heat generated in the display panel 100. The heat dissipation layer 200 may include a metal layer, such as graphite, silver (Ag), copper (Cu), and aluminum (Al) having a high thermal conductivity.

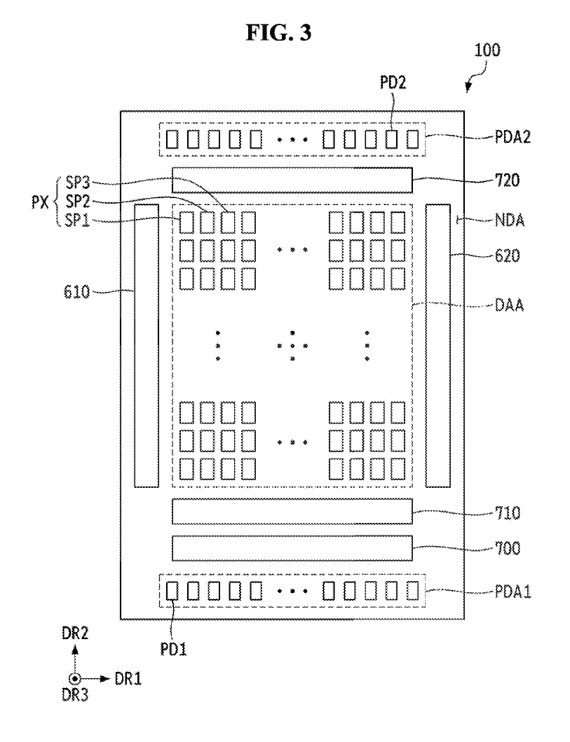

The circuit board 300 may be electrically connected to a plurality of first pads PD1 (see FIG. 3) of a first pad area PDA1 (see FIG. 3) of the display panel 100 using a conductive adhesive member, such as an anisotropic conductive film. The circuit board 300 may be a flexible printed circuit board made of a flexible material, or a flexible film. Although the circuit board 300 is unfolded in the example shown in FIG. 1, the circuit board 300 may be bent. When the circuit board 300 is bent, one end of the circuit board 300 may be located on the rear surface of the display panel 100 and/or the rear surface of the heat dissipation layer 200. The other end of the circuit board 300 may be connected to a plurality of first pads PD1 (see FIG. 3) of the first pad area PDA1 (see FIG. 3) of the display panel 100 using a conductive adhesive member. One end of the circuit board 300 may be opposite to the other end of the circuit board 300.

The timing control circuit 400 may receive digital video data and timing signals from the outside. The timing control circuit 400 may generate a scan-timing control signal SCS, an emission-timing control signal ECS, and a data-timing control signal DCS for controlling the display panel 100 in response to the timing signals. The timing control circuit 400 may output the scan-timing control signal SCS to the scan driver 610 and output the emission-timing control signal ECS to the emission driver 620. The timing control circuit 400 may output the digital video data and the data-timing control signal DCS to the data driver 700.

A power supply circuit 500 may generate a plurality of panel driving voltages in response to a power voltage from the outside. For example, the power supply circuit 500 may generate a first driving voltage VSS, a second driving voltage VDD, and a third driving voltage VINT to apply them to the display panel 100.

Each of the timing control circuit 400 and the power supply circuit 500 may be implemented as an integrated circuit (IC) and attached to a surface of the circuit board 300. The scan-timing control signal SCS, the emission-timing control signal ECS, the digital video data DATA, and the data-timing control signal DCS from the timing control circuit 400 may be supplied to the display panel 100 through the circuit board 300. The first driving voltage VSS, the second driving voltage VDD, and the third driving voltage VINT of the power supply circuit 500 may be supplied to the display panel 100 through the circuit board 300.

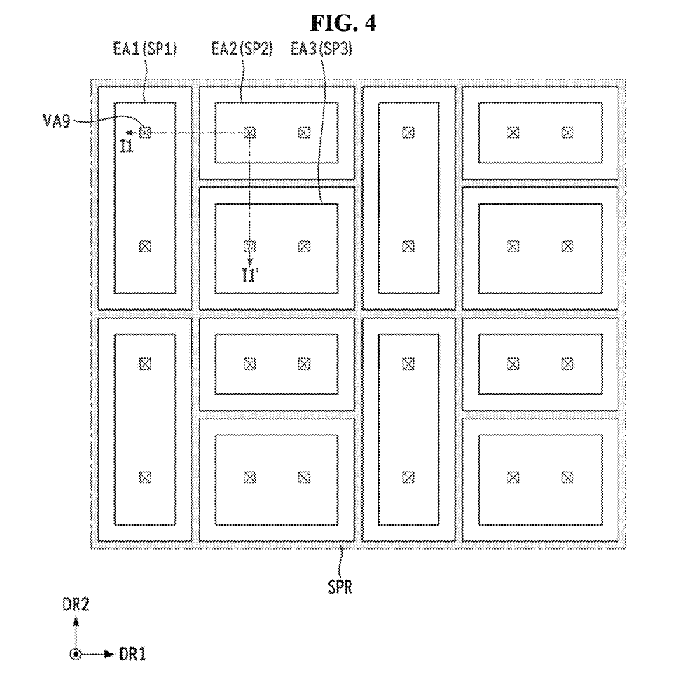

Alternatively, each of the timing control circuit 400 and the power supply circuit 500 may be located in the non-display area NDA of the display panel 100, similarly to the scan driver 610, the emission driver 620 and the data driver 700. In this instance, the timing control circuit 400 may include a plurality of timing transistors, and each power supply circuit 500 may include a plurality of power transistors. A plurality of timing transistors and a plurality of power transistors may be formed via a semiconductor process and may be formed on the semiconductor substrate SUB (see FIG. 6). For example, the plurality of timing transistors and the plurality of power transistors may be formed of CMOS transistors. It should be understood, however, that the embodiments of the present disclosure are not limited thereto. Each of the timing control circuit 400 and the power supply circuit 500 may be located between the data driver 700 and the first pad area PDA1 (see FIG. 4).

FIG. 3 is a view showing an example of a layout of a display panel according to one or more embodiments of the present disclosure.

Referring to FIG. 3 the display area DAA of the display panel 100 includes a plurality of pixels PX arranged in a matrix. The non-display area NDA of the display panel 100 includes the scan driver 610, the emission driver 620, the data driver 700, a first distribution circuit 710, a second distribution circuit 720, a first pad area PDA1, and a second pad area PDA2.

The scan driver 610 may be located on a first side of the display area DAA, and the emission driver 620 may be located on a second side of the display area DAA. For example, the scan driver 610 may be located on one side of the display area DAA in the first direction DR1, and the emission driver 620 may be located on the opposite side of the display area DAA in the first direction DR1. For example, the scan driver 610 may be located on the left side of the display area DAA, and the emission driver 620 may be located on the right side of the display area DAA. It should be understood, however, that the embodiments of the present disclosure are not limited thereto. The scan driver 610 and the emission driver 620 may be located on both the first and second sides of the display area DAA.

The first pad area PDA1 may include a plurality of first pads PD1 connected to pads or bumps of the circuit board 300 through a conductive adhesive member. The first pad area PDA1 may be located on a third side of the display area DAA. For example, the first pad area PDA1 may be located on one side of the display area DAA in the second direction DR2. The first pad area PDA1 may be located on the outer side of the data driver 700 in the second direction DR2. That is to say, the first pad area PDA1 may be located closer to the edge of the display panel 100 than the data driver 700 is.

The second pad area PDA2 may include a plurality of second pads PD2 which is test pads for testing whether the display panel 100 operates normally. The plurality of second pads PD2 may be connected to a jig or a probe pin during an inspection process, or may be connected to a circuit board for inspection. The circuit board for testing may be a printed circuit board made of a rigid material or a flexible printed circuit board made of a flexible material.

The second pad area PDA2 may be located on a fourth side of the display area DAA. For example, the second pad area PDA2 may be located on the opposite side of the display area DAA in the second direction DR2. The second pad area PDA2 may be located on the outer side of the second distribution circuit 720 in the second direction DR2. That is to say, the second pad area PDA2 may be located closer to the edge of the display panel 100 than the second distribution circuit 720.

The first distribution circuit 710 distributes data voltages applied via the first pad area PDA1 to a plurality of data lines DL. For example, the first distribution circuit 710 may divide the data voltages applied via one first pad PD1 of the first pad area PDA1 into P data lines DL, thereby reducing the number of the plurality of first pads PD1, where P is a positive integer equal to or greater than two. The first distribution circuit 710 may be located on the third side of the display area DAA of the display panel 100. For example, the first distribution circuit 710 may be located on one side of the display area DAA in the second direction DR2. That is to say, the first distribution circuit 710 may be located on the lower side of the display area DAA.

The second distribution circuit 720 distributes signals applied through the second pad area PDA2 to the scan driver 610, the emission driver 620, and the data lines DL. The second pad area PDA2 and the second distribution circuit 720 may be elements to inspect the operation of each of the pixels PX in the display area DAA. The second distribution circuit 720 may be located on the fourth side of the display area DAA of the display panel 100. For example, the second distribution circuit 720 may be located on the opposite side of the display area DAA in the second direction DR2. That is to say, the second distribution circuit 720 may be located on the upper side of the display area DAA.

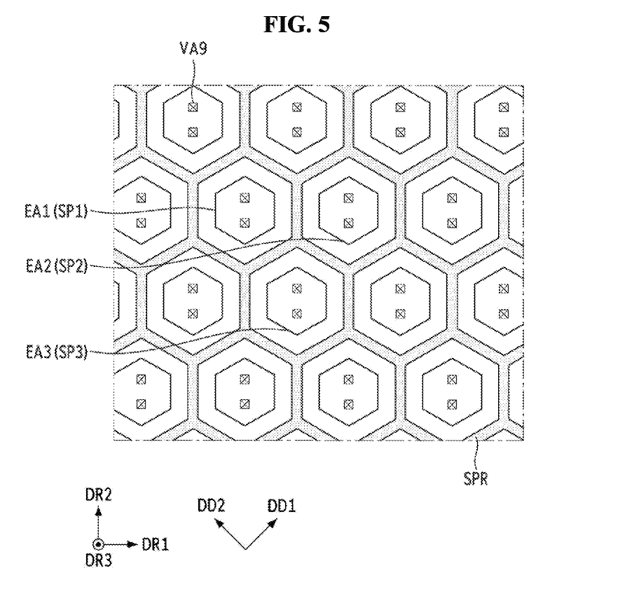

FIGS. 4 and 5 are layout diagrams showing examples of the display area of FIG. 3.

Referring to FIGS. 4 and 5, each of the plurality of pixels PX includes a first emission area EA1 that is the emission area of the first sub-pixel SP1, a second emission area EA2 that is the emission area of the second sub-pixel SP2, and a third emission area EA3 that is the emission area of the third sub-pixel SP3.

Each of the first emission area EA1, the second emission area EA2, and the third emission area EA3 may have a polygonal shape, a circular shape, an elliptical shape, or an irregular shape when viewed from the top.

The maximum length of the first emission area EA1 in the first direction DR1 may be less than the maximum length of the second emission area EA2 in the first direction DR1 and may be less than the maximum length of the third emission area EA3 in the first direction DR1. The maximum length of the second emission area EA2 in the first direction DR1 may be substantially equal to the maximum length of the third emission area EA3 in the first direction DR1.

The maximum length of the first emission area EA1 in the second direction DR2 may be greater than the maximum length of the second emission area EA2 in the second direction DR2 and may be greater than the maximum length of the third emission area EA3 in the second direction DR2. The maximum length of the second emission area EA2 in the second direction DR2 may be less than the maximum length of the third emission area EA3 in the second direction DR2.

As shown in FIG. 4, in each of the plurality of pixels PX, the first emission area EA1 and the second emission area EA2 may be adjacent to each other in the first direction DR1. In addition, the first emission area EA1 and the third emission area EA3 may be adjacent to each other in the first direction DR1. In addition, the second emission area EA2 and the third emission area EA3 may be adjacent to each other in the second direction DR2. The first emission area EA1, the second emission area EA2, and the third emission area EA3 may have different respective areas.

The first emission area EA1, the second emission area EA2, and the third emission area EA3 may have a hexagonal shape consisting of six straight lines, as shown in FIG. 5, when viewed from the top. It should be understood, however, that the embodiments of the present disclosure are not limited thereto. The first emission area EA1, the second emission area EA2 ,and the third emission area EA3 may have a polygonal shape other than a hexagon, a circular shape, an elliptical shape, or an irregular shape when viewed from the top.

As shown in FIG. 5, the first emission area EA1 and the second emission area EA2 may be adjacent to each other in the first direction DR1, the second emission area EA2 and the third emission area EA3 may be adjacent to each other in a first diagonal direction DD1, and the first emission area EA1 and the third emission area EA3 may be adjacent to each other in a second diagonal direction DD2. The first diagonal direction DD1 refer to a direction between the first direction DR1 and the second direction DR2, and refers to a direction inclined by 45 degrees relative to the first direction DR1 and the second direction DR2. The second diagonal direction DD2 may be orthogonal to the first diagonal direction DD1.

The first sub-pixel SP1 may output the first light that has passed through a first color filter from among the lights output from the first emission area EA1, the second sub-pixel SP2 may output the second light that has passed through a second color filter from among the lights output from the second emission area EA2, and the third sub-pixel SP3 may output the third light that has passed through a third color filter from among the lights output from the third emission area EA3.

The first light, the second light, and the third light described above may be lights of different wavelength ranges. For example, one of the first to third lights may be light in a blue wavelength range, another one may be light in a green wavelength range, and the other one may be light in a red wavelength range. The blue wavelength range may refer that the main peak wavelength of light lies in the wavelength range of approximately 370 nm to approximately 480 nm, the green wavelength range may refer that the main peak wavelength of light lies in the wavelength range of approximately 480 nm to approximately 560 nm, and the red wavelength range may refer to that the main peak wavelength of light lies in the wavelength range of approximately 600 nm to approximately 750 nm.

Although each of the plurality of pixels PX includes three emission areas EA1, EA2, and EA3 in the example shown in FIGS. 4 and 5, the embodiments of the present disclosure are not limited thereto. For example, each of the plurality of pixels PX may include four emission areas.

In addition, the layout of the emission areas of the plurality of pixels PX is not limited to that shown in FIGS. 4 and 5. For example, the emission areas of the plurality of pixels PX may have a stripe structure in which the emission areas are arranged in the first direction DR1, a PenTile^{®} matrix in which the emission areas have a diamond arrangement (PenTile^{®} being a registered trademark of Samsung Display Co., Ltd., Republic of Korea), or a hexagonal structure in which emission areas having a hexagonal shape when viewed from the top are arranged as shown in FIG. 5.

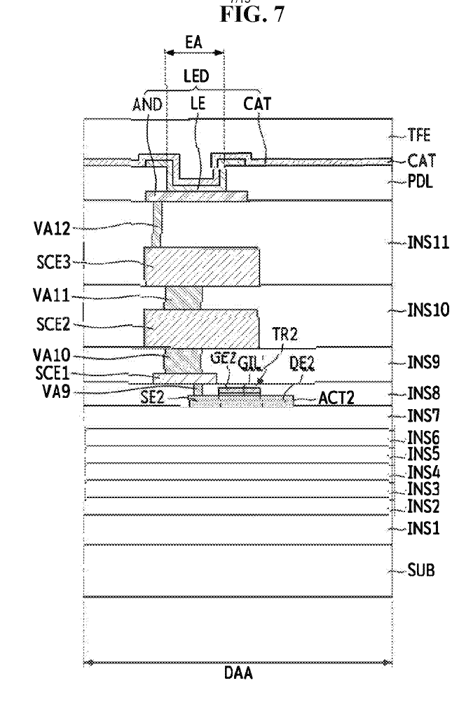

FIG. 6 is a cross-sectional view of a driving circuit of the display area DAA and a circuit of a pixel of the non-display area NDA of FIGS. 3, and 7 is a cross-sectional view of a circuit of a pixel and a light-emitting element LED of FIG. 3.

As illustrated in FIGS. 6 and 7, a first transistor TR1, a capacitor 810, a second transistor TR2, and a light-emitting element LED may be located in the display area DAA.

The capacitor 810 may be located on the semiconductor substrate SUB (e.g., wafer) in the display area DAA (as used herein, “located on” may mean “above”). For example, a first insulating layer INS1 may be located between the semiconductor substrate SUB and the capacitor 810, and the above-described capacitor 810 may be located on the first insulating layer INS1. The capacitor 810 may include a metal-oxide-metal (MOM) capacitor 810.

The capacitor 810 may include a plurality of capacitor electrodes. For example, the capacitor 810 may include a first capacitor electrode CPE1 on the first insulating layer INS1, a second capacitor electrode CPE2 on a second insulating layer INS2, a third capacitor electrode CPE3 on a third insulating layer INS3, a fourth capacitor electrode CPE4 on a fourth insulating layer INS4, and a fifth capacitor electrode CPE5 on a fifth insulating layer INS5. The first to fifth capacitor electrodes CPE1 to CPE5 may be connected to each other by a plurality of first via electrodes VA1. For example, the first capacitor electrode CPE1 and the second capacitor electrode CPE2 may be connected to each other through the first via electrode VA1 penetrating the second insulating layer INS2, the second capacitor electrode CPE2 and the third capacitor electrode CPE3 may be connected to each other through the first via electrode VA1 penetrating the third insulating layer INS3, the third capacitor electrode CPE3 and the fourth capacitor electrode CPE4 may be connected to each other through the first via electrode VA1 penetrating the fourth insulating layer INS4, and the fourth capacitor electrode CPE4 and the fifth capacitor electrode CPE5 may be connected to each other through the first via electrode VA1 penetrating the fifth insulating layer INS5.

A first capacitor connection electrode CCE1 and a counter gate electrode CGE may be located on the capacitor 810. For example, the first capacitor connection electrode CCE1 and the counter gate electrode CGE may be located on a sixth insulating layer INS6 in the display area DAA.

The first transistor TR1 may be located on the first capacitor connection electrode CCE1 and the counter gate electrode CGE. For example, the first transistor TR1 may be located on the first capacitor connection electrode CCE1 and the counter gate electrode CGE in the display area DAA.

The first transistor TR1 may include a first gate electrode GE1, a first source electrode SE1 of a first active layer ACT1, and a first drain electrode DE1 of the first active layer ACT1. The first transistor TR1 described above may be an oxide-based transistor (e.g., an oxide semiconductor transistor). For example, the first transistor TR1 may be an N-type oxide-based transistor. In other words, the first transistor TR1 may include an oxide semiconductor (or an oxide semiconductor material). Because the oxide semiconductor has high carrier mobility and low leakage current, the voltage drop is not large even if the driving time is long. For example, by virtue of the oxide semiconductor, the color change of an image due to a voltage drop is not significant even during low-frequency driving, allowing for low-frequency driving. Accordingly, the first transistor TR1 includes the oxide semiconductor material, so that it is possible to implement a display device having reduced power consumption while reducing or preventing leakage current.

The first active layer ACT1 may be located on a seventh insulating layer INS7. For example, the first active layer ACT1 may be located on the seventh insulating layer INS7 in the display area DAA. The first active layer ACT1 may include an oxide. For example, the first active layer ACT1 may be a semiconductor layer that includes indium-gallium-zinc-oxide (IGZO) or indium-gallium-zinc-tin oxide (IGZTO).

A gate-insulating layer GIL may be located between the first active layer ACT1 and the first gate electrode GE1. For example, the gate-insulating layer GIL may be located between the first active layer ACT1 and the first gate electrode GE1 in the display area DAA.

The first gate electrode GE1 may be located on the gate-insulating layer GIL to overlap a channel region of the first active layer ACT1 in the display area DAA.

The counter gate electrode CGE may be located to cover the channel region of the first active layer ACT1. For example, the counter gate electrode CGE may be located between the channel region of the first active layer ACT1 and the sixth insulating layer INS6 in the display area DAA. The counter gate electrode CGE may reduce or prevent light from entering the channel region, thereby reducing or preventing a leakage current of the first transistor TR1 by an external light.

A second capacitor connection electrode CCE2 and a first power connection electrode PCE1 may be located on an eighth insulating layer INS8. For example, the second capacitor connection electrode CCE2 and the first power connection electrode PCE1 may be located on the eighth insulating layer INS8 in the display area DAA.

One side of the second capacitor connection electrode CCE2 may be connected to the first capacitor connection electrode CCE1 through a third via electrode VA3. The other side of the second capacitor connection electrode CCE2 may be connected to the first drain electrode DE1 of the first transistor TR1 through a fourth via electrode VA4.

One side of the first power connection electrode PCE1 may be connected to the counter gate electrode CGE through a fifth via electrode VA5. The other side of the first power connection electrode PCE1 may be connected to the first source electrode SE1 of the first transistor TR1 through a sixth via electrode VA6.

A second power connection electrode PCE2 may be located on the first power connection electrode PCE1. The second power connection electrode PCE2 may be located on the first power connection electrode PCE1 in the display area DAA. The second power connection electrode PCE2 may be located on a ninth insulating layer INS9. The second power connection electrode PCE2 may be connected to the first power connection electrode PCE1 through a seventh insulating layer INS7.

A third power connection electrode PCE3 may be located on the second power connection electrode PCE2. For example, the third power connection electrode PCE3 may be located on the second power connection electrode PCE2 in the display area DAA. The third power connection electrode PCE3 may be located on a tenth insulating layer INS10. The third power connection electrode PCE3 may be connected to the second power connection electrode PCE2 through an eighth via electrode VA8.

An eleventh insulating layer INS11 may be located on the third power connection electrode PCE3 and the tenth insulating layer INS10.

As illustrated in FIG. 7, the second transistor TR2 may be located on the seventh insulating layer INS7 in the display area DAA. The second transistor TR2 may include a second gate electrode GE2, a second source electrode SE2 of a second active layer ACT2, and a second drain electrode DE2 of the second active layer ACT2. The second transistor TR2 described above may be an oxide-based transistor (e.g., an oxide semiconductor transistor). For example, the second transistor TR2 may be the same oxide transistor as the first transistor TR1 described above.

The second active layer ACT2 may be located on the seventh insulating layer INS7. For example, the second active layer ACT2 may be located on the seventh insulating layer INS7 in the display area DAA. The second active layer ACT2 may include an oxide.

The second gate electrode GE2 may be located on a gate-insulating layer GIL’ to overlap a channel region of the second active layer ACT2.

A first source connection electrode SCE1 may be located on the eighth insulating layer INS8 in the display area DAA. The first source connection electrode SCE1 may be connected to the second source electrode SE2 through a ninth via electrode VA9.

A second source connection electrode SCE2 may be located on the first source connection electrode SCE1 in the display area DAA. For example, the second source connection electrode SCE2 may be located on the ninth insulating layer INS9. The second source connection electrode SCE2 may be connected to the first source connection electrode SCE1 through a tenth via electrode VA10.

A third source connection electrode SCE3 may be located on the second source connection electrode SCE2 in the display area DAA. For example, the third source connection electrode SCE3 may be located on the tenth insulating layer INS10. The third source connection electrode SCE3 may be connected to the second source connection electrode SCE2 through an eleventh via electrode VA11.

A light-emitting element LED may be located on the second transistor TR2 and the third source connection electrode SCE3. For example, the light-emitting element LED may be located on the eleventh insulating layer INS11. The light-emitting element LED may include a first electrode AND (e.g., an anode electrode), a light-emitting layer LE, and a second electrode CAT (e.g., a cathode electrode).

The first electrode AND may be located on the eleventh insulating layer INS11 in the display area DAA. The first electrode AND may be connected to the third source connection electrode SCE3 through a twelfth via electrode VA12.

A pixel-defining layer PDL defining an emission area EA may be located on the first electrode AND. The pixel-defining layer PDL may be located on the edge of the first electrode AND.

The light-emitting layer LE may be located on the pixel-defining layer PDL. The light-emitting layer LE may be connected to the first electrode AND in the emission area EA of the display area DAA.

The second electrode CAT may be located on the first electrode AND and the pixel-defining layer PDL.

An encapsulation layer TFE may be located on the second electrode CAT. The encapsulation layer TFE may be formed of a composite film including an inorganic layer, an organic layer, and an inorganic layer. The encapsulation layer TFE may reduce or prevent moisture from permeating into the light-emitting layer LE. A color filter may be located on the encapsulation layer TFE.

The first transistor TR1, the second transistor TR2, and the light-emitting element LED of the aforementioned display area DAA may be included in a pixel PX (e.g. a sub-pixel). In other words, one sub-pixel may include the first transistor TR1, the second transistor TR2, and the light-emitting element LED.

As illustrated in FIG. 6, a driving circuit may be located in the non-display area NDA. The driving circuit may include at least one among the scan driver 610, an emission driver 620, or the data driver 700 (e.g., see FIG. 3).

The driving circuit may include a third transistor TR3 located in the non-display area NDA. The third transistor TR3 may be a metal-oxide-semiconductor field effect transistor (MOSFET). For example, third transistor TR3 may be a P-type MOSFET.

The semiconductor substrate SUB may be a substrate doped with first-type impurities.

In the non-display area NDA, a well region WA may be located on the top surface of the semiconductor substrate SUB. The well region WA maybe an area doped with second-type impurities. The second-type impurities may be different from the above-described first-type impurities. For example, in a case where the first-type impurity is a P-type impurity, the second-type impurity may be an N-type impurity. Alternatively, in a case where the first-type impurity is an N-type impurity, the second-type impurity may be a P-type impurity.

The well region WA may include a source region SA corresponding to the source electrode of the third transistor TR3 and a drain region DA corresponding to the drain electrode of the third transistor TR3.

A gate-insulating layer GI may be located between a gate electrode GE and the well region WA. A side surface insulating layer SW may be located on the side surface of the gate electrode GE.

The source region SA may be connected to a source connection electrode SCE, and the drain region DA may be connected to a drain connection electrode DCE.

The source connection electrode SCE and the drain connection electrode DCE may be located on the third transistor TR3. For example, the source connection electrode SCE and the drain connection electrode DCE may be located on the first insulating layer INS1.

The source connection electrode SCE may be connected to the source region SA through a contact hole penetrating the first insulating layer INS1.

The drain connection electrode DCE may be connected to the drain region DA through a contact hole penetrating the first insulating layer INS1.

A connection electrode 820 may be located on the third transistor TR3, the source connection electrode SCE, and the drain connection electrode DCE of the non-display area NDA. For example, the connection electrode 820 may be located on the second insulating layer INS2. The connection electrode 820 may include a plurality of connection electrodes. For example, the connection electrode 820 may include a first connection electrode CE1 on the second insulating layer INS2, a second connection electrode CE2 on the third insulating layer INS3, a third connection electrode CE3 on the fourth insulating layer INS4, a fourth connection electrode CE4 on the fifth insulating layer INS5, and a fifth connection electrode CE5 on the sixth insulating layer INS6.

The first to fifth connection electrodes CE1 to CE5 may be connected to each other by a plurality of fourteenth via electrodes VA14. For example, the first connection electrode CE1 and the second connection electrode CE2 may be connected to each other through the fourteenth via electrode VA14 penetrating the third insulating layer INS3, the second connection electrode CE2 and the third connection electrode CE3 may be connected to each other through the fourteenth via electrode VA14 penetrating the fourth insulating layer INS4, the third connection electrode CE3 and the fourth connection electrode CE4 may be connected to each other through the fourteenth via electrode VA14 penetrating the fifth insulating layer INS5, and the fourth connection electrode CE4 and the fifth connection electrode CE5 may be connected to each other through the fourteenth via electrode VA14 penetrating the sixth insulating layer INS6.

The connection electrode 820 may be connected to the drain connection electrode DCE through a thirteenth via electrode VA13. For example, the first connection electrode CE1 may be connected to the drain connection electrode DCE through the thirteenth via electrode VA13.

According to one or more embodiments, because the transistors TR1 and TR2 of the display area DAA are oxide-based transistors, short-channel effects of the transistors TR1 and TR2 may be reduced or prevented in the high-resolution display device 10. In addition, because the transistor TR3 of the driving circuit is formed of MOSFET, the switching speed of the driving circuit may be improved. In other words, according to one or more embodiments, because the driving circuit of the non-display area NDA includes MOSFET while the pixel PX (or the sub-pixel) of the display area DAA includes an oxide-based transistor, short-channel effects can be reduced or prevented in the display area DAA while ensuring a high driving speed of the driving circuits in the non-display area NDA.

In addition, according to one or more embodiments, because a transistor is not formed between the capacitor 810 and the semiconductor substrate SUB of the display area DAA, an arrangement space of the capacitor 810 may be sufficiently secured and the capacitance of the capacitor 810 may be improved.

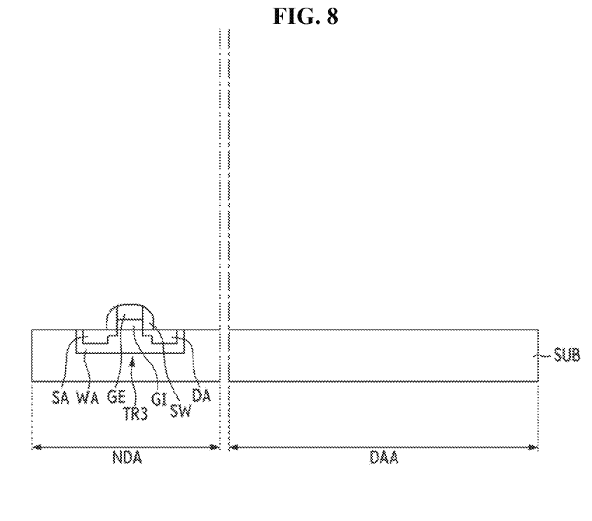

FIGS. 8-10, and 11 are process cross-sectional views for illustrating a method of manufacturing a display device according to one or more embodiments. For example, FIGS. 8-11 may be process cross-sectional views for illustrating a method of manufacturing the display device of FIG. 6 described above.

First, as illustrated in FIG. 8, the third transistor TR3 may be formed on the semiconductor substrate SUB of the non-display area NDA. The third transistor TR3 may be a MOSFET.

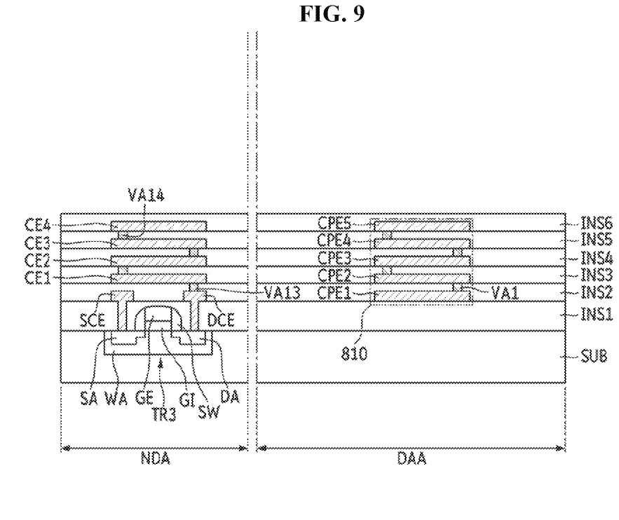

Thereafter, as illustrated in FIG. 9, the first insulating layer INS1 may be placed on the entire surface of the semiconductor substrate SUB including the third transistor TR3. Next, the first capacitor electrode CPE1 may be formed on the first insulating layer INS1 of the display area DAA while the source connection electrode SCE connected to the source region SA of the third transistor TR3 through a contact hole of the first insulating layer INS1, and the drain connection electrode DCE connected to the drain region DA of the third transistor TR3 through a contact hole of the first insulating layer INS1, are formed on the first insulating layer INS1 in the non-display area NDA. Next, the second capacitor electrode CPE2, the third capacitor electrode CPE3, the fourth capacitor electrode CPE4, and the fifth capacitor electrode CPE5 may be formed respectively on the second insulating layer INS2, the third insulating layer INS3, the fourth insulating layer INS4, and the fifth insulating layer INS5, while the first connection electrode CE1, the second connection electrode CE2, the third connection electrode CE3, and the fourth connection electrode CE4 are formed respectively on the second insulating layer INS2, the third insulating layer INS3, the fourth insulating layer INS4, and the fifth insulating layer INS5. At this time, the connection electrodes adjacent to each other may be connected by the fourteenth via electrode VA14 and the capacitor electrodes adjacent to each other may be connected by the first via electrode VA1. Thereafter, the sixth insulating layer INS6 may be formed on the fourth connection electrode CE4 and the fifth capacitor electrode CPE5.

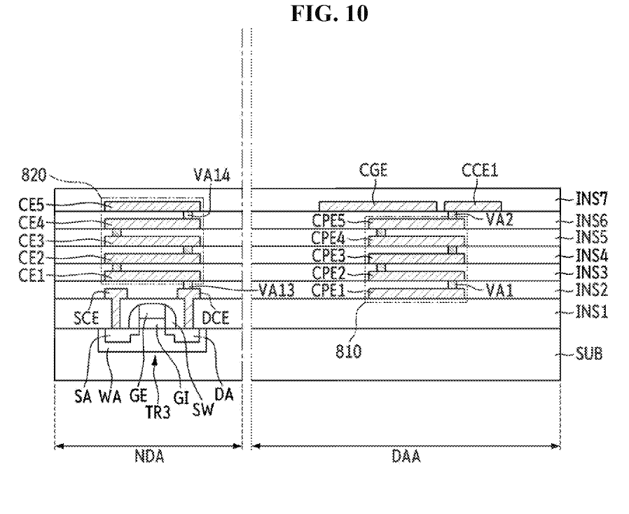

Next, as illustrated in FIG. 10, the fifth connection electrode CE5 may be formed on the sixth insulating layer INS6 of the non-display area NDA, and the counter gate electrode CGE and the first capacitor connection electrode CCE1 may be formed on the sixth insulating layer INS6 of the display area DAA. At this time, the fifth connection electrode CE5 may be connected to the fourth connection electrode CE4 though the fourteenth via electrode VA14, and the first capacitor connection electrode CCE1 may be connected to the fifth capacitor electrode CPE5 through a second via electrode VA2. Thereafter, the seventh insulating layer INS7 may be formed on the fifth connection electrode CE5, the counter gate electrode CGE, and the first capacitor connection electrode CCE1.

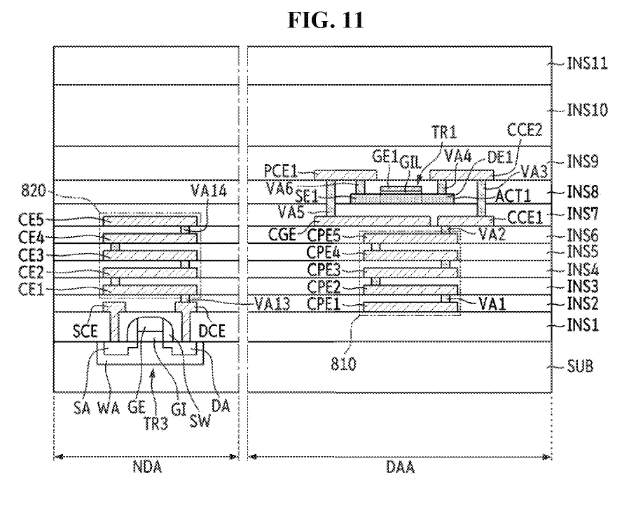

Thereafter, as illustrated in FIG. 11, the first transistor TR1 may be formed on the seventh insulating layer INS7 of the display area DAA. The first transistor TR1 may be an oxide-based transistor. The first drain electrode DE1 of the first transistor TR1 may be connected to the first capacitor connection electrode CCE1 through fourth via electrode VA4, through the second capacitor connection electrode CCE2, and through the third via electrode VA3. The first source electrode SE1 of the first transistor TR1 may be connected to the counter gate electrode CGE through the sixth via electrode VA6, the first power connection electrode PCE1, and the fifth via electrode VA5.

Next, as illustrated in FIG. 6, the second power connection electrode PCE2 connected to the first power connection electrode PCE1, and the third power connection electrode PCE3 connected to the second power connection electrode PCE2, may be formed on the first transistor TR1 of the display area DAA.

The display device 10 may be applied to a variety of electronic devices. An electronic device according to one or more embodiments includes the display device 10 described above, and may further include a module or device having additional features in addition to the display device 10.

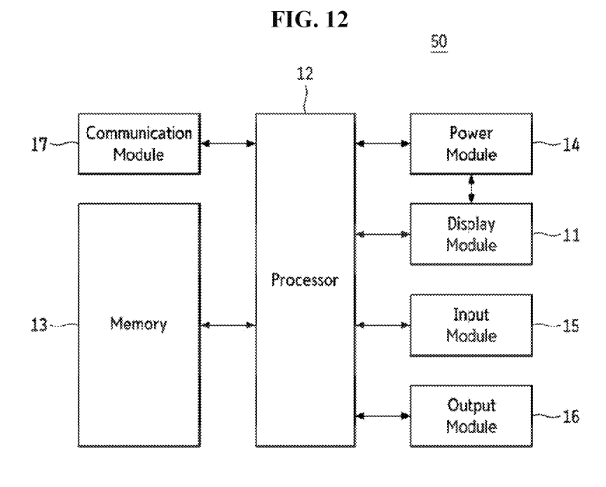

FIG. 12 is of block diagram of an electronic device according to one or more embodiments of the present disclosure. Referring to FIG. 12, an electronic device 50 according to one or more embodiments of the present disclosure may include a display module 11, a processor 12, a memory 13, and a power module 14. The electronic device 50 may further include an input module 15, a non-image output module 16, and/or a communication module 17.

The electronic device 50 may output various information in the form of images through the display module 11. When the processor 12 executes an application stored in the memory 13, image information provided by the application may be provided to the user through the display module 11. The power module 14 may include a power supply module, such as a power adapter and a battery device, and a power conversion module that converts the power supplied by the power supply module to generate power required for the operation of the electronic device 50. The input module 15 may provide input information to the processor 12 and/or the display module 11. The non-image output module 16 may receive information other than images from the processor 12, such as sound, haptic, and light information, and provide it to the user. The communication module 17 is responsible for transmitting and receiving information between the electronic device 50 and an external device, and may include a receiving unit and a transmitting unit.

At least one of the elements of the electronic device 50 described above may be included in the display devices according to the embodiments described above. In addition, some of the individual modules functioning as a single module may be included in the display device while some others may be provided separately from the display device. For example, the display device may include the display module 11, and the processor 12, the memory 13, and the power module 14 may be implemented as other devices inside the electronic device 50 instead of the display device.

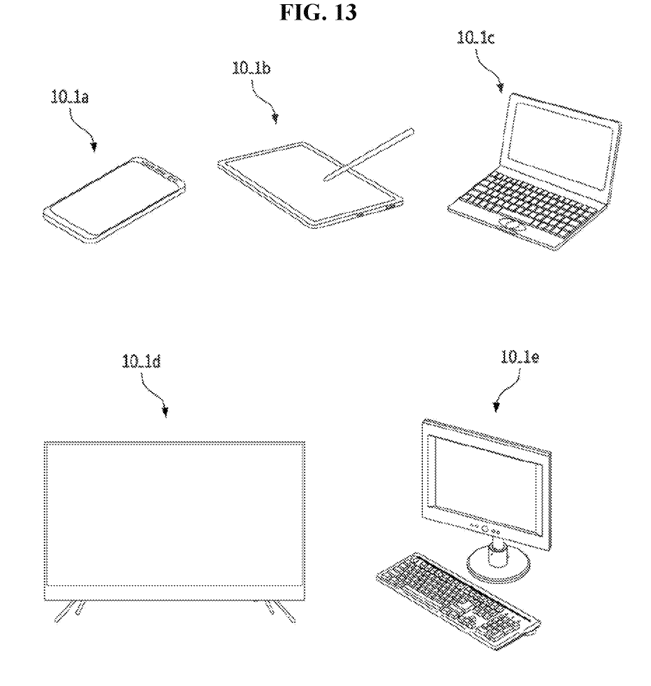

FIGS. 13, 14, and 15 are schematic diagrams of electronic devices according to various embodiments. FIGS. 13-15 show examples of a variety of electronic devices employing the display devices 10 according to the embodiments.

FIG. 11 shows a smartphone 10_1a, a tablet PC 10_1b, a laptop computer 10_1c, a TV 10_1d, and a desktop monitor 10_1eas examples of the electronic devices.

The smartphone 10_1a may include an input module, such as a touch sensor and a communication module in addition to a display module 11. The smartphone 10_1a may process information received through the communication module or other input modules and display the information through the display module of the display device.

The tablet PCs 10_1b, the laptop computer 10_1c, the TV 10_1d and the desktop monitor 10_1e may include display modules and input modules similar to the smartphone 10_1a, and may further include communication modules as desired.

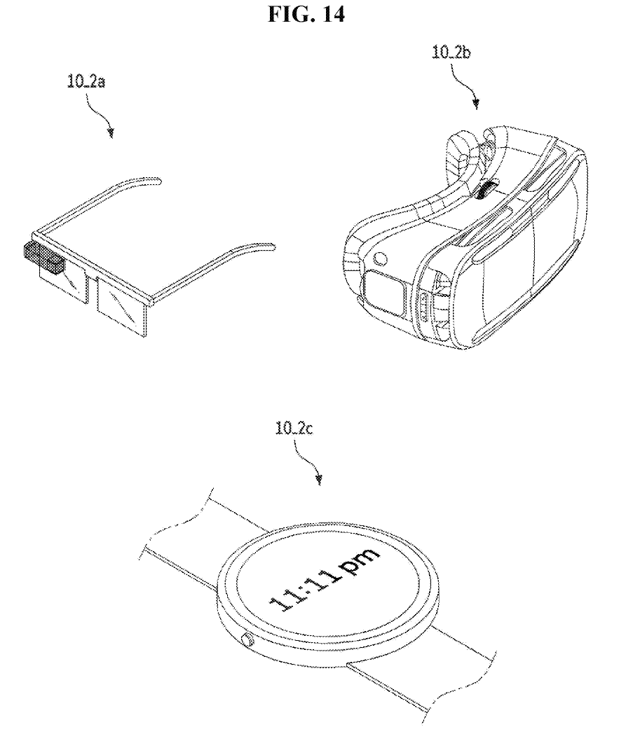

FIG. 14 shows examples of a wearable electronic device employing an electronic device including a display module. The wearable electronic devices may be smart glasses 10_2a, a head-mounted display 10_2b, a smart watch 10_2c, etc.

The smart glasses 10_2a and the head-mounted display 10_2b may include a display module that outputs display images, and a reflector that reflects the output display images and provides it to the user's eyes, thereby providing the user with images of virtual reality or augmented reality on the screen.

The smart watch 10_2c includes a biometric sensor as an input device, and may provide the user with biometric information recognized by the biometric sensor through the display module.

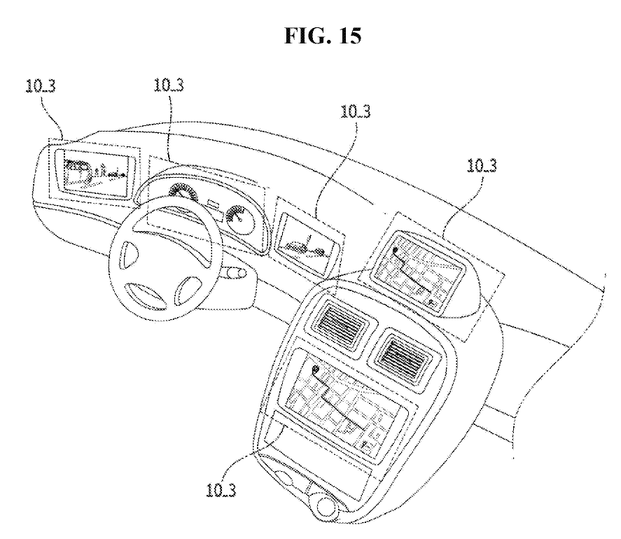

FIG. 15 shows an example of an electronic device including a display module applied to a vehicle. For example, an electronic device 10_3 may be applied to the instrument cluster, the center fascia, etc., of a vehicle, or may be applied to a center information display (CID) located at the dashboard of a vehicle, or may be used as a room mirror display on the behalf of the side mirrors of a vehicle.

In concluding the detailed description, those skilled in the art will appreciate that many variations and modifications can be made to the embodiments without substantially departing from the aspects of the present disclosure. Therefore, the disclosed embodiments are used in a generic and descriptive sense only and not for purposes of limitation.

What is claimed is:

1. A display device comprising:
a substrate having a display area and a non-display area;
a first transistor and a second transistor at the display area, at least one of which comprising an oxide semiconductor transistor;
a first electrode above the second transistor;
a pixel-defining layer above the first electrode;
a light-emitting layer above the pixel-defining layer to be connected to the first electrode;
a second electrode above the light-emitting layer; and
a third transistor comprising a field effect transistor at the non-display area.

2. The display device of claim 1, wherein the oxide semiconductor transistor comprises an N-type transistor.

3. The display device of claim 1, wherein the field effect transistor comprises a P-type transistor.

4. The display device of claim 1, wherein the oxide semiconductor transistor comprises an indium-gallium-zinc-oxide or indium-gallium-zinc-tin oxide.

5. The display device of claim 1, wherein the field effect transistor comprises a MOSFET.

6. The display device of claim 1, further comprising a capacitor in the display area.

7. The display device of claim 6, wherein the capacitor is between the substrate and the first transistor.

8. The display device of claim 6, wherein the capacitor comprises capacitor electrodes.

9. The display device of claim 6, wherein the capacitor comprises a metal-oxide-metal capacitor.

10. The display device of claim 6, wherein the capacitor is connected to the first transistor.

11. The display device of claim 1, further comprising a power connection electrode in the display area.

12. The display device of claim 11, wherein the power connection electrode is connected to the first transistor.

13. The display device of claim 1, further comprising a connection electrode in the non-display area.

14. The display device of claim 13, wherein the connection electrode is provided as multiple connection electrodes.

15. The display device of claim 13, wherein the connection electrode is connected to the third transistor.

16. An electronic device comprising:
a display device comprising:
a substrate having a display area and a non-display area;
a first transistor and a second transistor at the display area, at least one of which comprising an oxide semiconductor transistor;
a first electrode above the second transistor;
a pixel-defining layer above the first electrode;
a light-emitting layer above the pixel-defining layer and connected to the first electrode;
a second electrode above the light-emitting layer; and
a third transistor comprising a field effect transistor at the non-display area.

17. The electronic device of claim 16, wherein the oxide semiconductor transistor comprises an N-type transistor.

18. The electronic device of claim 16, wherein the field effect transistor comprises a P-type transistor.

19. The electronic device of claim 16, wherein the oxide semiconductor transistor comprises an indium-gallium-zinc-oxide or indium-gallium-zinc-tin oxide.

20. The electronic device of claim 16, wherein the electronic device comprises a smartphone, a tablet PC, a laptop computer, a TV, a desktop monitor, smart glasses, a smart watch, a head-mounted display, or a display for vehicles.
